(19) United States
(12) Patent Application Publication
(10) Pub. No.: US 2026/0347567 A1
(43) Pub. Date: Nov. 5, 2026

(54) THERMALLY CONDUCTIVE INJECTION MOULDING MATERIAL

(71) Applicant: KERAFOL Holding GmbH, Eschenbach/Opf. (DE)

(72) Inventors: Sabine KOPPE, Eschenbach (DE); Wolfgang HÖFER, Hahnbach (DE)

(21) Appl. No.: 19/476,031

(22) PCT Filed: Apr. 8, 2024
(86) PCT No.: PCT/EP2024/059436

§ 371 Date: Oct. 16, 2025

(30) Foreign Application Priority Data
Apr. 18, 2023 (DE) 10 2023 109 660.5

(51) Int. Cl. C08K 3/22; B29C 45/00; B29K 9/06; B29K 505/02; B29K 509/02; C08K 3/08

(52) U.S. Cl. CPC C08K 3/22; B29C 45/0001; B29C 45/0013; C08K 3/08; B29K 2009/06; B29K 2505/02; B29K 2509/02; C08K 2003/0812; C08K 2003/2227; C08K 2201/001

(57) ABSTRACT

A thermally conductive injection molding material that can be processed in an injection molding process includes a matrix which includes at least one thermoplastic elastomer, wherein the matrix contains thermally conductive particles.

The invention relates to a thermally conductive injection moulding material, comprising a matrix consisting of at least one thermoplastic material, wherein the matrix contains thermally conductive particles.

Corresponding thermally conductive injection moulding materials are generally characterised by a thermoplastic matrix having thermally conductive particles contained therein, and are known in principle from the prior art, fundamentally in different embodiments.

Corresponding thermally conductive injection moulding materials are typically present as a granulate material that can be processed in an injection moulding process. The processing of corresponding injection moulding materials typically includes melting a respective injection moulding material, then transferring the respective injection moulding material into a molten mass and injecting the molten mass into a shaping cavity of an injection mould.

A component or a component arrangement may already be contained in the shaping cavity of the injection mould, onto which the molten mass is sprayed on at least in portions, or which is overmoulded at least in portions with the molten mass. The purpose of injection moulding or overmoulding can in particular be that heat resulting during operation of the component or the component arrangement can be dissipated via the injection moulding material. This can be the case in particular for electrical or electronic components or component arrangements.

Known thermally conductive injection moulding materials are in need of improvement or development in particular with respect to their thermal properties, in particular their thermal conductivity, which is typically (only) approximately 0.1 W/mK.

Furthermore, there is a need for improvement or development of known thermally conductive injection moulding materials in view of the ability to adapt to the most different possible, possibly complex, geometries of a respective component or a respective component arrangement, in order to ensure the most optimal possible thermal contact between the component or the component arrangement and the injection moulding material or the thermally conductive plastics body formed therefrom, and thus the most optimal possible dissipation of thermal energy through the injection moulding material or the thermally conductive plastics body formed thereby.

Proceeding herefrom, the object of the present invention is that of specifying an improved thermally conductive injection moulding material.

The invention is achieved in particular by a thermally conductive injection moulding material according to independent claim 1. The claims dependent thereon relate to possible embodiments of the thermally conductive injection moulding material according to independent claim 1.

A first aspect of the invention relates to a thermally conductive injection moulding material (in the following only the term “injection moulding material” is used). The term injection moulding material indicates the property of the injection moulding material to be able to be processed in an injection moulding process. The processability of the injection moulding material in an injection moulding process implies in particular that the injection moulding material can be transferred into a molten mass (melt) by heating, which melt can be injected into a shaping cavity of an injection mould. The injection moulding material, in any case before it has been processed in an injection moulding process, is typically present as a granulate material, which is why the injection moulding material can optionally also be referred to as or considered as an injection moulding granulate material.

The injection moulding material is thermally conductive and thus has thermally conductive properties which, as follows below, result in particular from a fraction of thermally conductive particles distributed in a thermoplastic matrix.

The injection moulding material thus comprises a thermoplastic matrix. The particularity of the matrix of the injection moulding material is that it does not consist of a conventional thermoplastics, but rather of a thermoplastic elastomer, TPE for short. The injection moulding material thus comprises a matrix consisting of a thermoplastic elastomer. On account of their chemical/physical structure, i.e. in particular the presence of physical cross-linking points, thermoplastic elastomers have different properties compared with conventional thermoplastics. In particular, owing to their chemical/physical structure, thermoplastic elastomers are characterised, compared with conventional thermoplastics, by a reduced hardness and thus a greater softness, which forms a basis for the injection moulding material being able to adapt to the most different possible, possibly complex, geometries and/or unevennesses of a component or a component arrangement on which the (molten) injection moulding material is sprayed, at least in portions, in the context of an injection moulding process or which is overmoulded, at least in portions, by the (molten) injection moulding material in the context of an injection moulding process. Accordingly, on account of the properties of the thermoplastic elastomer that forms the matrix, the injection moulding material offers the most optimal possible thermal contact between the component or the component arrangement and the injection moulding material or the thermally conductive plastics body formed therefrom after cooling and hardening, and thus to ensure the most optimal possible dissipation of thermal energy through the injection moulding material or through the thermally conductive plastics body formed thereby.

In order to increase the thermal conductivity of the injection moulding material, the matrix contains thermally conductive particles. The fraction of the thermally conductive particles in the matrix is so high that they essentially influence or essentially define the thermal conductivity of the injection moulding material. Specifically, the injection moulding material can have a thermal conductivity of at least 0.5 W/mK, in particular of at least 0.6 W/mK, more particularly of at least 0.7 W/mK, more particularly of at least 0.8 W/mK, more particularly of at least 0.9 W/mK, more particularly of at least 1.0 W/mK, more particularly of at least 1.1 W/mK, more particularly of at least 1.2 W/mK, more particularly of at least 1.3 W/mK, more particularly of at least 1.4 W/mK, more particularly of at least 1.5 W/mK, more particularly of at least 1.6 W/mK, more particularly of at least 1.7 W/mK, more particularly of at least 1.8 W/mK, more particularly of at least 1.9 W/mK, more particularly of at least 2.0 W/mK, more particularly of at least 2.1 W/mK, more particularly of at least 2.2 W/mK, more particularly of at least 2.3 W/mK, more particularly of at least 2.4 W/mK, more particularly of at least 2.5 W/mK, more particularly of at least 2.6 W/mK, more particularly of at least 2.7 W/mK, more particularly of at least 2.8 W/mK, more particularly of at least 2.9 W/mK, more particularly of at least 3.0 W/mK. The above-mentioned values can also define respective upper and lower limits of intervals. The fraction of the thermally conductive particles in the matrix can accordingly be selected to be so high that the thermal conductivities of the injection moulding material, set out above, are present. Furthermore, other parameters of the thermally conductive particles that influence the thermal conductivity of the injection moulding material, such as the type, shape, distribution, etc., can be selected such that the thermal conductivities of the injection moulding material, set out above, are present. The thermal conductivity of the injection moulding material can for example be measured according to the standard ASTM D5470, ASTM D7896-19 or ASTM E1225-20.

The property combination, resulting from the composition of the injection moulding material, of softness or shape-adaptability and comparatively high thermal conductivity results in an improved injection moulding material.

The injection moulding material can therefore be used in particular for forming thermally conductive plastics bodies, which are provided for dissipating thermal energy (heat) resulting during operation of a component or a component arrangement—this can be the case in particular for electrical or electronic components or component arrangements. Corresponding thermally conductive plastics bodies can be produced in that the (molten) injection moulding material is sprayed onto a respective component or onto a respective component arrangement, at least in portions, in the context of an injection moulding process, or a respective component or a respective component arrangement is overmoulded with the (molten) injection moulding material, at least in portions, in the context of an injection moulding process. In all cases, in the context of a corresponding injection moulding process at least one surface of a respective component or a respective component arrangement is covered with the injection moulding material, such that after cooling and hardening a thermally conductive bond between the component or the component arrangement and the thermally conductive plastics body formed by cooling or hardening of the injection moulding material results.

In an expedient embodiment, the matrix is formed by a thermoplastic elastomer based on a styrene polymer or a styrene copolymer. Corresponding thermoplastic elastomers, which are based on a styrene polymer or a styrene copolymer, have a particular adaptability or softness which, as described, has a positive influence on the property profile of the injection moulding material.

In a particularly expedient embodiment, the matrix is formed by a thermoplastic elastomer based on a styrene-butadiene-styrene copolymer. Corresponding thermoplastic elastomers, which are based on a styrene-butadiene-styrene copolymer, SBS, have a particular adaptability or softness which, as described, has a positive influence on the property profile of the injection moulding material.

In a preferred embodiment, the matrix is formed by styrene-ethylene-butylene-styrene, SEBS. With SEBS as the matrix, a particularly good adaptability or softness could be demonstrated in tests, which, as described, has a positive influence on the property profile of the injection moulding material. SEBS is furthermore characterised by a continuous use temperature in a range between −40 °C and 120 °C, and therefore there is no risk of the injection moulding material or a thermally conductive plastics body formed therefrom softening in an undesired manner, and thus possibly even detaching from the component or the component arrangement, at typical operating temperatures of electrical or electronic components or component arrangements. The use of SEBS as the matrix of the injection moulding material thus ensures the possibility of dissipating thermal energy from a component that generates thermal energy during operation, or a corresponding component arrangement, over a wide temperature range. Further advantageous properties of SEBS are its mechanical stability and weather-resistance, which makes it conceivable to use corresponding thermally conductive plastics bodies in different weather conditions.

In all embodiments, the hardness or softness of the injection moulding material or of a thermally conductive plastics body formed therefrom can be in a range between 10 and 80 Shore A, in particular between 15 and 70 Shore A, more particularly between 15 and 60 Shore A, more particularly between 15 and 50 Shore A, more particularly between 15 and 40 Shore A, more particularly between 15 and 30 Shore A. The hardness of the injection moulding material or of a thermally conductive plastics body formed therefrom can be set in particular by the type, fraction and distribution of respective thermally conductive particles. The hardness according to Shore A can be measured e.g. according to the standard ASTM D 2240.

The thermally conductive particles can in particular be metal particles and/or metal oxide particles. Thus, metal particles and/or metal oxide particles can be contained in the matrix of the injection moulding material. Therefore, the injection moulding material can contain thermally conductive particles which are formed by metal and/or metal oxide particles or comprise such.

In an expedient embodiment, the thermally conductive particles are aluminium particles, aluminium oxide (Al₂O₃) particles, aluminium hydroxide (Al(OH)₃) particles, or mixtures of at least two of the above. Thus, aluminium particles and/or aluminium oxide particles and/or aluminium hydroxide particles or mixtures of at least two of the above can be contained in the matrix of the injection moulding material. Therefore, the injection moulding material can contain thermally conductive particles which are or comprise aluminium particles, aluminium oxide particles, aluminium hydroxide particles, or mixtures of at least two of the above. The aluminium particles, aluminium oxide (Al₂O₃) particles, aluminium hydroxide (Al(OH)₃) particles can have e.g. a round or rounded geometry or basic shape. Alternatively or in addition, plate-like or plate-shaped geometries or basic shapes are in principle also conceivable.

In an alternative or additional embodiment, the thermally conductive particles may be titanium particles, titanium oxide (TiO, TiO₂ or Ti₂O₃) particles, titanium hydroxide particles, or mixtures of at least two of the above. Thus, titanium particles and/or titanium oxide particles and/or titanium hydroxide particles or mixtures of at least two of the above can be contained in the matrix of the injection moulding material. Therefore, the injection moulding material can contain thermally conductive particles which are or comprise titanium particles, titanium oxide particles, titanium hydroxide particles, or mixtures of at least two of the above. The titanium particles, titanium oxide (TiO, TiO₂ or Ti₂O₃) particles, titanium hydroxide particles can have e.g. a round or rounded geometry or basic shape. Alternatively or in addition, plate-like or plate-shaped geometries or basic shapes are in principle also conceivable.

In an alternative or additional embodiment, the thermally conductive particles may be zirconium particles, zirconium oxide (ZrO₂) particles, zirconium hydroxide (Zr(OH)₄) particles, or mixtures of at least two of the above. Thus, zirconium particles and/or zirconium oxide particles and/or zirconium hydroxide particles or mixtures of at least two of the above can be contained in the matrix of the injection moulding material. Therefore, the injection moulding material can contain thermally conductive particles which are or comprise zirconium particles, zirconium oxide particles, zirconium hydroxide particles, or mixtures of at least two of the above. The zirconium particles, zirconium oxide (ZrO₂) particles, zirconium hydroxide (Zr(OH)₄) particles can have e.g. a round or rounded geometry or basic shape. Alternatively or in addition, plate-like or plate-shaped geometries or basic shapes are in principle also conceivable.

In an alternative or additional embodiment, the thermally conductive particles may be magnesium particles, magnesium oxide (MgO) particles, magnesium hydroxide (Mg(OH)₂) particles, or mixtures of at least two of the above. Thus, magnesium particles and/or magnesium oxide particles and/or magnesium hydroxide particles or mixtures of at least two of the above can be contained in the matrix of the injection moulding material. Therefore, the injection moulding material can contain thermally conductive particles which are or comprise magnesium particles, magnesium oxide particles, magnesium hydroxide particles, or mixtures of at least two of the above. The magnesium particles, magnesium oxide (MgO) particles, magnesium hydroxide (Mg(OH)₂) particles can have e.g. a round or rounded geometry or basic shape. Alternatively or in addition, plate-like or plate-shaped geometries or basic shapes are in principle also conceivable.

In an alternative or additional embodiment, the thermally conductive particles may be iron particles, iron oxide (Fe₂O₃ or Fe₃O₄) particles, iron hydroxide (Fe(OH)₃) particles, or mixtures of at least two of the above. Thus, iron particles and/or iron oxide particles and/or iron hydroxide particles or mixtures of at least two of the above can be contained in the matrix of the injection moulding material. Therefore, the injection moulding material can contain thermally conductive particles which are or comprise iron particles, iron oxide particles, iron hydroxide particles, or mixtures of at least two of the above. Therefore, in particular also ferrites or ferritic compounds are also possible. The iron particles, iron oxide (Fe₂O₃ or Fe₃O₄) particles, iron hydroxide (Fe(OH)₃) particles can have e.g. a round or rounded geometry or basic shape. Alternatively or in addition, plate-like or plate-shaped geometries or basic shapes are in principle also conceivable.

In an alternative or additional embodiment, the thermally conductive particles may be particles based on nitride, or boron nitride particles. Thus, nitride-based particles, in particular boron nitride particles, can be contained in the matrix of the injection moulding material. Therefore, the injection moulding material can thermally conductive The nitride-based particles, in particular the boron nitride particles, can have e.g. a round or rounded geometry or basic shape. Alternatively or in addition, plate-like or plate-shaped geometries or basic shapes are in principle also conceivable.

In an alternative or additional embodiment, the thermally conductive particles may be carbon-based particles, such as graphite and/or carbon black.

At least two of the embodiments of thermally conductive particles, set out above, can be mixed with one another.

For all embodiments, it is in principle the case that the thermally conductive particles can have spherical geometries or basic shapes, i.e. e.g. ball-like or ball-shaped geometries or basic shapes or round or rounded geometries or basic shapes, or non-spherical geometries or basic shapes, such as plate-like or plate-shaped geometries or basic shapes. The geometry or basic shape of the thermally conductive particles and the resulting arrangement or orientation possibilities within the matrix can have an influence on the thermal conductivity of the injection moulding material, and therefore the selection of the geometry or basic shape of the thermally conductive particles can take place in view of a desired thermal conductivity of the injection moulding material.

The fraction by weight of the thermally conductive particles in the matrix can—in principle depending on their chemical composition and their geometry or basic shape—be in a range between 5 and 95 wt. %. In particular, the fraction by weight of the thermally conductive particles in the matrix can be in a range above 5 wt. %, more particularly above 10 wt. %, more particularly above 15 wt. %, more particularly above 20 wt. %, more particularly above 25 wt. %, more particularly above 30 wt. %, more particularly above 35 wt. %, more particularly above 40 wt. %, more particularly above 45 wt. %, more particularly above 50 wt. %, more particularly above 55 wt. %, more particularly above 60 wt. %, more particularly above 65 wt. %, more particularly above 70 wt. %, more particularly above 75 wt. %, more particularly above 80 wt. %, more particularly above 85 wt. %, more particularly above 90 wt. %. The above-mentioned values can also define respective upper and lower limits of intervals. It could be shown, on the basis of tests, that a fraction by weight of the thermally conductive particles in the matrix in a range between 60 and 80 wt. %, in particular between 70 and 80 wt. %, both makes it possible for a desired thermal conductivity of the injection moulding material to be achieved and also ensures a desired processability of the injection moulding material in an injection moulding process. Therefore, a preferred fraction of thermally conductive particles in the matrix can be approximately 75 wt. %. In particular, despite the comparatively high fraction of thermally conductive particles there is a sufficient flowability of the melted or plasticised injection moulding material, such that overmoulding of a component is possible.

The size of the thermally conductive particles can, in particular depending on the chemical composition, be e.g. in a range between 1 and 300 μm, in particular between 3 and 300 μm, more particularly between 5 and 300 μm, more particularly between 10 and 300 μm, more particularly between 15 and 300 μm, more particularly between 20 and 300 μm, more particularly between 25 and 300 μm. The upper limit can, instead of 300 μm, also be 275 μm, 250 μm, 225 μm or 200 μm. It is therefore also conceivable for the size of the thermally conductive particles to be between 75 and 250 μm, more particularly between 100 and 225 μm, more particularly between 125 and 200 μm. In the case of (purely) aluminium-based thermally conductive particles, the particle size can in particular be in a range between 3 and 50 μm, in particular between 3 and 30 μm. In the case of aluminium oxide-based thermally conductive particles, the particle size can be e.g. in a range between 1 and 20 μm, in particular between 1 and 10 μm. In the case of aluminium hydroxide-based thermally conductive particles, the particle size can be e.g. in a range between 1 and 150 μm, in particular between 1 and 100 μm. In the case of thermally conductive particles based on other elements, such as boron or nitride (compounds), the particle size can in particular be in a range between 100 and 250 μm, in particular between 100 and 200 μm.

Boron or nitride-based particles, in particular boron nitride particles, can, if present, have e.g. a plate-like or plate-shaped geometry or basic shape in all the embodiments. Alternatively or in addition, round or rounded geometries or basic shapes are in principle also conceivable.

In all the embodiments, the particle size can advantageously be selected such that the thermally conductive particles can be arranged, in the matrix, in the manner of a thermally conductive network. Corresponding applies for the fraction by weight of the thermally conductive particle in the matrix.

The matrix of the injection moulding material can contain just one type of thermally conductive particle. It is also conceivable, however, for the matrix of the injection moulding material to contain a first and at least one second type of thermally conductive particle. The mixing of thermally conductive particles that differ in at least one chemical and/or physical parameter provides a possibility for purposely influencing the property profile of the injection moulding material, i.e. in particular also its thermal properties, more particularly its thermal conductivity.

In a conceivable embodiment, the matrix of the injection moulding material can contain two different types of thermally conductive particles, i.e. thermally conductive particles of a first and a second type.

The fraction by weight of the thermally conductive particles of the first type is in a range between 5 and 75 wt. % and the fraction by weight of the thermally conductive particles of the second type is in a range between 5 and 75 wt. %, wherein the sum of the fractions does not exceed 100 wt. %. In particular, the sum of the fractions of the thermally conductive particles of the first type and the at least one second type is in a range between 50 and 80 wt. %, more particularly in a range between 60 and 75 wt. %.

The thermally conductive particles of the first and second type can each have a round or rounded geometry or basic shape, or a plate-like or plate-shaped geometry or basic shape. In this case, the thermally conductive particles of the first type can have a geometry or basic shape that corresponds to or differs from the geometry of the thermally conductive particles of the second types. Therefore, the thermally conductive particles of the first and the second type can each have a round or rounded geometry or basic shape, or a plate-like or plate-shaped geometry or basic shape. Alternatively, the thermally conductive particles of the first type can have a round or rounded geometry or basic shape, and the thermally conductive particles of the second type can have a plate-like or plate-shaped geometry or basic shape, or vice versa. The above applies in principle for all specific embodiments of the injection moulding material, and thus irrespective of the chemical composition of the thermally conductive particles of the first and second type.

In a specific embodiment by way of example, the thermally conductive particles of the first type can be aluminium oxide particles, in particular having a round or rounded geometry or basic shape, and the thermally conductive particles of the second type can be nitride particles, in particular boron nitride particles, in particular having a plate-like or plate-shaped geometry or basic shape. Corresponding nitride particles, in particular boron nitride particles, which are characterised by a comparatively high thermal conductivity and a low electrical conductivity, can, in addition to an influence on the thermal conductivity of the injection moulding material, also exert an influence on the mechanical properties of the injection moulding material or of a thermally conductive plastics body formed therefrom. As mentioned, the fraction by weight of the thermally conductive particles of the first type can be in a range between 5 and 75 wt. % and the fraction by weight of the thermally conductive particles of the second type can be in a range between 5 and 75 wt. %, wherein the sum of the fractions does not exceed 100 wt. %. In particular, the sum of the fractions of the thermally conductive particles of the first and the at least one second type is in a range between 50 and 80 wt. %, more particularly in a range between 60 and 75 wt. %.

For the processability in an injection moulding process, in addition to the melting temperature of the matrix—this is in any case typically approximately 170 °C for SEBS—the melt volume flow rate of the injection moulding material in a molten state is a decisive variable. In a molten state, the injection moulding material can have a melt volume flow rate in a range between 4 and 20 g/10 min (at 190 °C or 230 °C /2.16 kg), in particular between 5 and 15 g/10 min (at 190 °C or 230 °C/2.16 kg), more particularly between in particular between 5 and 10 g/10 min (at 190 °C or 230 °C/2.16 kg), more particularly between in particular between 5 and 7.5 g/10 min (at 190 °C or 230 °C/2.16 kg). In a specific embodiment, the injection moulding material can have a melt volume flow rate of approximately 6 g/10 min. The comparatively high melt volume flow rate allows for reliable overmoulding of components even with complex geometries, and prevents fragile components or component portions from being damaged in the context of the overmoulding. The comparatively high melt volume flow rate of the injection moulding material furthermore allows good filling of the cavity of a respective injection mould and reduces the formation of ridges and air inclusions. The melt volume flow rate can be measured e.g. according to DIN EN ISO 1133.

The combustion behaviour may be an important property for various applications or fields of use of the injection moulding material or of a thermally conductive plastics body formed therefrom—this applies in particular for electrical or electronic applications or fields of use. The injection moulding material may have a combustion behaviour of the class v0 according to UL-94. The injection moulding material can thus have a very high rating, which is associated with a significant safety advantage precisely in the case of high-temperature applications.

Furthermore, a particularly reliable thermal index, RTI for short, is required for various applications or fields of use of the injection moulding material or of a thermally conductive plastics body formed therefrom—this in turn applies in particular for electrical or electronic applications or fields of use, such as in the case of accumulator or battery applications. The injection moulding material can thus have a relative thermal index, RTI, of at least 80 °C, in particular at least 90 °C, more particularly at least 100 °C. The RTI can be determined e.g. according to the UL standard 746B.

Furthermore, a particular (particularly low) electrical conductivity, and therefore a particular electrical resistance, is required for various applications or fields of use of the injection moulding material or of a thermally conductive plastics body formed therefrom—this in turn applies in particular for electrical or electronic applications or fields of use. The injection moulding material can thus have a comparatively low electrical conductivity. The dielectric strength of the injection moulding material can be at least 2.0 kV/mm, in particular at least 2.5 kV/mm, more particularly at least 3.0 kV/mm, more particularly at least 3.5 kV/mm, more particularly at least 4.0 kV/mm, more particularly at least 4.5 kV/mm, more particularly at least 5.0 kV/mm. Embodiments of the injection moulding material having a dielectric strength of at least 6.0 kV/mm, in particular at least 7.0 kV/mm, more particularly at least 8.0 kV/mm, more particularly at least 9.0 kV/mm, more particularly at least 10.0 kV/mm, more particularly at least 11.0 V/mm, more particularly at least 12.0 kV/mm, more particularly at least 13.0 kV/mm, more particularly at least 14.0 kV/mm more particularly at least 15.0 kV/mm are also conceivable. The above-mentioned values are all also considered to be upper or lower limits of an interval. The injection moulding material can thus be electrical insulating in general and in particular up to at least 2 kV. The electrical dielectric strength can be measured e.g. according to the standard ASTM D 149.

The thermally conductive particles can have a particle size in a range between 15 and 380 μm. The particle size can in particular vary depending on the chemical composition of the respective thermally conductive particles.

For example aluminium-based particles having a particle size in a range between 10 and 45 μm, in particular between 15 and 35 μm, and aluminium hydroxide-based particles having a particle size in a range between 90 and 120 μm, in particular between 100 and 110 μm, have proven expedient. The above-mentioned values in particular apply for a mixture of aluminium-based particles and aluminium hydroxide-based particles, wherein the first-mentioned particles can be round or rounded and the second-mentioned particles can be plate-like or plate-shaped, or vice versa.

Aluminium-based particles having a particle size in a range between 3 and 15 μm, in particular between 3 and 10 μm, and boron nitride-based particles having a particle size in a range between 220 and 380 μm, in particular between 240 and 360 μm, have also proven expedient. The above-mentioned values in particular apply for a mixture of aluminium-based particles and boron nitride-based particles, wherein the first-mentioned particles can be plate-like or plate-shaped and the second-mentioned particles can be round or rounded, or vice versa.

The composition of the injection moulding material according to a first specific embodiment can be as follows: The matrix consisting of SEBS contains approximately 30 wt. % particles of aluminium having a round or rounded basic shape, and approximately 45 wt. % particles of aluminium hydroxide having a plate-like or plate-shaped basic shape. The matrix consisting of SEBS therefore makes up approximately 25 wt. % of the injection moulding material. The aluminium particles can be obtained e.g. from the company Benda-Lutz GmbH. The aluminium hydroxide particles can be obtained e.g. from the company Nabaltec AG. This embodiment can also be implemented with particles of aluminium having a plate-like or plate-shaped basic shape and with particles of aluminium hydroxide having a round or rounded basic shape.

The composition of the injection moulding material according to a second specific embodiment can be as follows: The matrix consisting of SEBS contains approximately 30 wt. % particles of aluminium oxide having a plate-like or plate-shaped basic shape, and approximately 30 wt. % particles of boron nitride having a round or rounded basic shape. The matrix consisting of SEBS therefore makes up approximately 25 wt. % of the injection moulding material. The aluminium oxide particles can be obtained e.g. from the companies Almatis GmbH, Bassermann, Huber Advanced Materials, Showa Denko or Silbelco. The boron nitride particles can be obtained e.g. from the companies 3M, Saint Gobain, Henze, Momentive or Kennametal. This embodiment can also be implemented with particles of aluminium oxide having a round or rounded basic shape and with particles of boron nitride having a plate-like or plate-shaped basic shape.

A second aspect of the invention relates to a method for processing an injection moulding material according to the first aspect of the invention. The method in particular comprises the steps of: Melting or plasticising the injection moulding material and injecting the melted or plasticised thermally conductive injection moulding material into a shaping cavity of an injection mould. The method can in principle be carried out with any injection moulding machine, which typically comprises a plasticiser unit for plasticising the injection moulding material, and/or an injection unit, e.g. formed by or comprising a screw that is movably mounted within a corresponding cylinder, for injecting the plasticised injection moulding material into a shaping cavity of an injection mould. The method can accordingly be implemented as an injection moulding process, in which the injection moulding material is melted or plasticised and injected into a shaping cavity of an injection mould.

A third aspect of the invention relates to a method for producing a component arrangement that is provided at least in portions with a thermally conductive layer formed by at least one thermally conductive plastics body 5 formed by cooling or hardening of the injection moulding material. The method in particular comprises the following steps: Providing at least one component that generates thermal energy (heat) in at least one operating state, in particular at least one electrical or electronic component that generates heat in at least one operating state, and overmoulding the at least one component, which generates heat in at least one operating state, at least in portions with a melted or plasticised injection moulding material according to the first aspect of the invention, forming the component arrangement. The overmoulding of the at least one component with the melted or plasticised injection moulding material can take place in the context of a injection moulding process in which the injection moulding material is melted or plasticised and injected into a shaping cavity of an injection mould, in which the at least one component is arranged or held, in order to be overmoulded at least in portions with the melted or plasticised injection moulding material.

A fourth aspect of the invention relates to a component arrangement which is produced according to a method according to the third aspect of the invention. The component arrangement typically consists of the at least one component, i.e. e.g. an electrical and/or electronic component, and the thermally conductive plastics body that covers said component at least in portions and is formed by cooling or hardening of the injection moulding material.

The geometry of the thermally conductive plastics body is thus based at least in portions on the geometry of the component, such that the thermally conductive plastics body rests flat on the surface of the component, at least in portions, which leads to a good heat transfer from the component to the thermally conductive plastics body.

Specifically, the component arrangement can be an electrical or electronic control system, in particular an electrical or electronic accumulator or battery control system for an accumulator or a battery, of an accumulator or battery-operated tool, such as a screwdriving tool. In this case, the component that is overmoulded at least in portions with the injection moulding material can be a printed circuit board fitted with one or more electrical and/or electronic structural elements, in particular a control board.

In all the embodiments, the geometry of the plastics body can comprise one or more cooling structures, e.g. cooling ribs, and/or one or more reinforcing structures, e.g. reinforcing ribs, which can be formed in one piece or integrally with the plastics body in the context of the injection moulding process by corresponding shaping of the cavity of the respective injection mould.

The spraying—similar would in principle apply for other types of application or fastening—of a corresponding thermally conductive plastics body from the injection moulding material onto a corresponding component makes it possible to reduce the operating temperature of the respective component or the corresponding component arrangement, which can significantly lengthen the lifetime of the component or the component arrangement.

All the statements relating to the injection moulding material according to the first aspect of the invention apply analogously for the method according to the second aspect of the invention, the method according to the third aspect of the invention, and for the component arrangement according to the fourth aspect of the invention, and vice versa.

The invention is explained again in the following, with reference to the embodiments shown in the figures, in which:

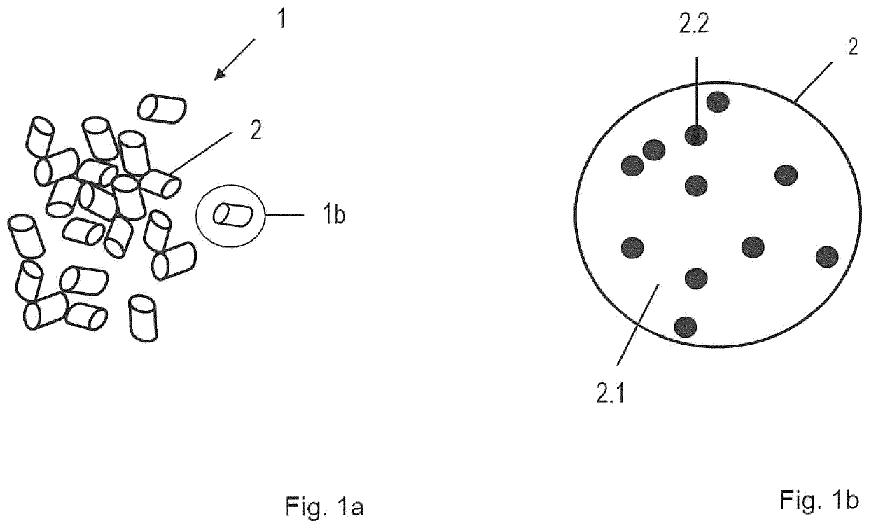

FIGS. 1a, 1b are schematic views of an injection moulding material according to an embodiment;

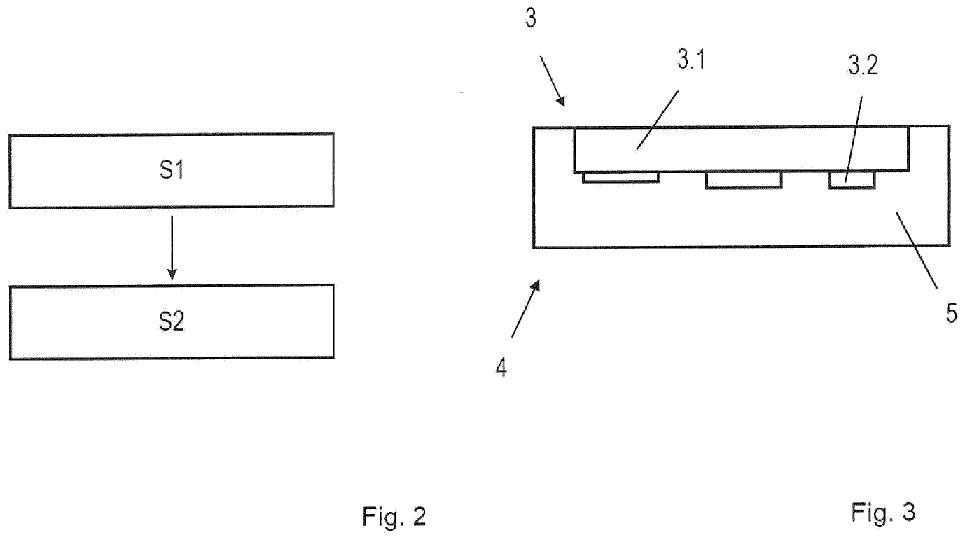

FIG. 2 is a flow diagram for illustrating the steps of a method according to an embodiment; and

FIG. 3 shows a component arrangement according to an embodiment.

FIGS. 1a and 1b are schematic views of a thermally conductive injection moulding material 1 (FIG. 1a) and an enlarged granulate material grain of such an injection moulding material (FIG. 1b). The injection moulding material 1 can be processed in an injection moulding process, which implies in particular that the injection moulding material 1 can be transferred into a molten mass (melt) by heating, which melt can be injected into a shaping cavity of an injection mould. The injection moulding material 1, in any case before it has been processed in an injection moulding process, is typically present as a granulate material, which is why the injection moulding material 1 can optionally also be referred to as or considered as an injection moulding granulate material. The individual grains of the granulate material are indicated in FIG. 1 by reference sign 2.

The injection moulding material 1 is thermally conductive and thus has thermally conductive properties which, as follows below, result in particular from a fraction of thermally conductive particles 2.2 distributed in a thermoplastic matrix 2.1, as indicated in the enlarged view according to FIG. 1b.

The injection moulding material 1 thus comprises a thermoplastic matrix 2.1 which consists of a thermoplastic elastomer, TPE for short. Therefore, owing to its chemical/physical structure, i.e. in particular the presence of physical cross-linking points, the matrix 2.1 of the injection moulding material 1 has different properties compared with matrices of conventional thermoplastic materials, such as a reduced hardness and thus a greater softness, which forms a basis for the injection moulding material 1 being able to adapt to the most different possible, possibly complex, geometries and/or unevennesses of a component 3 of a component arrangement 4 on which the (molten) injection moulding material 1 is sprayed, at least in portions, in the context of an injection moulding process or which is overmoulded, at least in portions, by the (molten) injection moulding material 1 in the context of an injection moulding process. Accordingly, on account of the properties of the thermoplastic elastomer that forms the matrix 2.1, the injection moulding material 1 offers the most optimal possible thermal contact between the component 3 or the component arrangement 4 and the injection moulding material 1 or the thermally conductive plastics body 5 formed therefrom after cooling and hardening, and thus to ensure the most optimal possible dissipation of thermal energy through the injection moulding material 1 or through the thermally conductive plastics body 5 formed thereby.

In order to increase the thermal conductivity of the injection moulding material 1, the matrix 2.1 contains thermally conductive particles 2.2. The fraction of the thermally conductive particles 2.2 in the matrix is so high that they essentially influence or essentially define the thermal conductivity of the injection moulding material 1. Specifically, the injection moulding material 1 can have a thermal conductivity of at least 1.5 W/mK, in particular of at least 2.0 W/mK. The fraction of the thermally conductive particles 2.2 in the matrix 2.1 can accordingly be selected to be so high that the thermal conductivities of the injection moulding material 1, set out above, are present. Furthermore, other parameters of the thermally conductive particles 2.2 that influence the thermal conductivity of the injection moulding material 1, e.g. type, shape, distribution, etc., can be selected such that the thermal conductivities of the injection moulding material 1, set out above, are present. The thermal conductivity of the injection moulding material 1 can for example be measured according to the standard ASTM D5470, ASTM D7896-19 or ASTM E1225-20.

The property combination, resulting from the composition of the injection moulding material 1, of softness or shape-adaptability and comparatively high thermal conductivity results in an improved injection moulding material 1.

The injection moulding material 1 can therefore be used in particular for forming thermally conductive plastics bodies 5 (cf. FIG. 3), which are provided for dissipating thermal energy (heat) resulting during operation of a component 3 or a component arrangement 4—this can be the case in particular for electrical or electronic components 3 or component arrangements 4. Corresponding thermally conductive plastics bodies 5 can be produced in that the (molten) injection moulding material 1 is sprayed onto a respective component 3 or onto a respective component arrangement 4, at least in portions, in the context of an injection moulding process, or a respective component 3 or a respective component arrangement 4 is overmoulded with the (molten) injection moulding material 1, at least in portions, in the context of an injection moulding process. In all cases, in the context of a corresponding injection moulding process at least one surface of a respective component 3 or a respective component arrangement 4 is covered or coated with the injection moulding material 1, such that after cooling and hardening a thermally conductive bond between the component 3 or the component arrangement 4 and the thermally conductive plastics body 5 formed by cooling or hardening of the injection moulding material 1 results.

The matrix 2.1 of the injection moulding material 1 can be formed by a thermoplastic elastomer based on a styrene polymer or a styrene copolymer. In the embodiment, the matrix 2.1 of the injection moulding material 1 is formed by a thermoplastic elastomer based on a styrene-butadiene-styrene copolymer; specifically, the matrix 2.1 of the injection moulding material 1 is formed by styrene-ethylene-butylene-styrene, SEBS. SEBS is furthermore characterised by a continuous use temperature in a range between −40 °C and 120 °C, and therefore there is no risk of the injection moulding material 1 or a thermally conductive plastics body 5 formed therefrom softening in an undesired manner, and thus possibly even detaching from the component 3 or the component arrangement 4, at typical operating temperatures of electrical or electronic components or component arrangements 4. The use of SEBS as the matrix 2.1 of the injection moulding material 1 thus ensures the possibility of dissipating thermal energy from a component 3 that generates thermal energy during operation, or a corresponding component arrangement 4, over a wide temperature range. Further advantageous properties of SEBS are its mechanical stability and weather-resistance, which makes it conceivable to use corresponding thermally conductive plastics bodies 5, formed from the injection moulding material 1, in different weather conditions.

The hardness or softness of the injection moulding material 1 or of a thermally conductive plastics body 5 formed therefrom can be in a range between 10 and 80 Shore A, in particular between 15 and 70 Shore A, more particularly between 15 and 60 Shore A, more particularly between 15 and 50 Shore A, more particularly between 15 and 40 Shore A, more particularly between 15 and 30 Shore A. The hardness of the injection moulding material 1 or of a thermally conductive plastics body 5 formed therefrom can be set in particular by the type, fraction and distribution of respective thermally conductive particles 2.2. The hardness according to Shore A can be measured e.g. according to the standard ASTM D 2240.

The thermally conductive particles 2.2 can in particular be metal particles and/or metal oxide particles. Thus, metal particles and/or metal oxide particles can be contained in the matrix 2.1 of the injection moulding material 1. Therefore, the injection moulding material 1 can contain thermally conductive particles which are formed by metal and/or metal oxide particles or comprise such.

The thermally conductive particles 2.2 can in particular be aluminium particles, aluminium oxide particles or aluminium hydroxide particles, or mixtures of at least two of the above. Thus, aluminium particles and/or aluminium oxide particles and/or aluminium hydroxide particles or mixtures of at least two of the above can be contained in the matrix of the injection moulding material 1. Therefore, the injection moulding material 1 can contain thermally conductive particles which are or comprise aluminium particles, aluminium oxide particles, aluminium hydroxide particles, or mixtures of at least two of the above.

The thermally conductive particles 2.2 can have spherical geometries or basic shapes, i.e. e.g. ball-like or ball-shaped geometries or basic shapes, or non-spherical geometries or basic shapes, such as plate-like or plate-shaped geometries or basic shapes. The geometry or basic shape of the thermally conductive particles 2.2 and the resulting arrangement or orientation possibilities within the matrix 2.1 can have an influence on the thermal conductivity of the injection moulding material 1, and therefore the selection of the geometry or basic shape of the thermally conductive particles 2.2 can take place in view of a desired thermal conductivity of the injection moulding material 1.

The fraction by weight of the thermally conductive particles in the matrix can—in principle depending on their chemical composition and their geometry or basic shape—be in a range between 5 and 95 wt. %. Expediently, the fraction by weight of the thermally conductive particles 2.2 in the matrix 2.1 is in a range between 60 and 80 wt. %, in particular between 70 and 80 wt. %, which both makes it possible for a desired thermal conductivity of the injection moulding material 1 to be achieved and also ensures a desired processability of the injection moulding material 1 in an injection moulding process. In particular, despite the comparatively high fraction of thermally conductive particles 2.2 there is a sufficient flowability of the melted or plasticised injection moulding material 1, such that overmoulding of a component 3 is possible.

The size of the thermally conductive particles 2.2 can be in a range between 25 and 300 μm, in particular between 50 and 275 μm, more particularly between 75 and 250 μm, more particularly between 100 and 225 μm, more particularly between 125 and 200 μm. For aluminium-based thermally conductive particles 2.2, the particle size can in particular be in a range between 50 and 100 μm, for thermally conductive particles 2.2 based on other elements, such as boron or nitride (compounds), the particle size can in particular be in a range between 100 and 200 μm.

The matrix 2.1 of the injection moulding material 1 can in principle contain just one type of thermally conductive particle 2.2. It is also conceivable, however, for the matrix 2.1 of the injection moulding material 1 to contain a first and at least one second type of thermally conductive particle 2.2. The mixing of thermally conductive particles 2.2 that differ in at least one chemical and/or physical parameter provides a possibility for purposely influencing the property profile of the injection moulding material 1, i.e. in particular also its thermal properties, more particularly its thermal conductivity.

In particular, the matrix 2.1 of the injection moulding material 1 can contain two different types of thermally conductive particles 2.2, i.e. thermally conductive particles 2.2 of a first and a second type. The fraction by weight of the thermally conductive particles 2.2 of the first type is in a range between 5 and 75 wt. % and the fraction by weight of the thermally conductive particles of the second type is in a range between 5 and 75 wt. %, wherein the sum of the fractions does not exceed 100 wt. %. In particular, the sum of the fractions of the thermally conductive particles of the first and the at least one second type is in a range between 50 and 80 wt. %, more particularly in a range between 60 and 75 wt. %.

The thermally conductive particles 2.2 of the first type can be aluminium oxide particles, and the thermally conductive particles 2.2 of the second type can be nitride particles, in particular boron nitride particles. Corresponding nitride particles, in particular boron nitride particles, which are characterised by a comparatively high thermal conductivity and a low electrical conductivity, can, in addition to an influence on the thermal conductivity of the injection moulding material 1, also exert an influence on the mechanical properties of the injection moulding material 1 or of a thermally conductive plastics body 5 formed therefrom. As mentioned, the fraction by weight of the thermally conductive particles 2.2 of the first type is in a range between 5 and 75 wt. % and the fraction by weight of the thermally conductive particles of the second type is in a range between 5 and 75 wt. %, wherein the sum of the fractions does not exceed 100 wt. %. In particular, the sum of the fractions of the thermally conductive particles 2.2 of the first and the at least one second type is in a range between 50 and 80 wt. %, more particularly in a range between 60 and 75 wt. %.

For the processability in an injection moulding process, in addition to the melting temperature of the matrix 2.1—this is in any case typically approximately 170 °C for SEBS-the melt volume flow rate of the injection moulding material 1 in a molten state is a decisive variable. In a molten state, the injection moulding material 1 can have a melt volume flow rate in a range between 4 and 20 g/10 min (at 190 °C/2.16 kg or 230 °C/2.16 kg). The comparatively high melt volume flow rate allows for reliable overmoulding of components 3 even with complex geometries, and prevents fragile components or component portions from being damaged in the context of the overmoulding. The comparatively high melt volume flow rate of the injection moulding material 1 furthermore allows good filling of the cavity of a respective injection mould and reduces the formation of ridges and air inclusions. The melt volume flow rate can be measured e.g. according to DIN EN ISO 1133.

The combustion behaviour may be an important property for various applications or fields of use of the injection moulding material 1 or of a thermally conductive plastics body 5 formed therefrom—this applies in particular for electrical or electronic applications or fields of use. The injection moulding material 1 may have a combustion behaviour of the class v0 according to UL-94. The injection moulding material 1 can thus have a very high rating, which is associated with a significant safety advantage precisely in the case of high-temperature applications.

Furthermore, a particularly reliable thermal index, RTI for short, is required for various applications or fields of use of the injection moulding material 1 or of a thermally conductive plastics body 5 formed therefrom-this in turn applies in particular for electrical or electronic applications or fields of use, such as in the case of accumulator or battery applications. The injection moulding material 1 can thus have a relative thermal index, RTI, of at least 80 °C, in particular at least 90 °C, more particularly at least 100 °C.

Furthermore, a particular (particularly low) electrical conductivity, and therefore a particular electrical resistance, is required for various applications or fields of use of the injection moulding material 1 or of a thermally conductive plastics body 5 formed therefrom-this applies in particular for electrical or electronic applications or fields of use. The injection moulding material 1 can thus have a comparatively low electrical conductivity. The dielectric strength of the injection moulding material 1 can be at least 3.0 kV/mm. The injection moulding material 1 can thus be electrical insulating up to at least 3.0 kV. The electrical dielectric strength can be measured e.g. according to the standard ASTM D 149.

The composition of the injection moulding material 1 according to a first specific embodiment can be as follows: The matrix 2.1 consisting of SEBS contains approximately 30 wt. % particles of aluminium having a round or rounded basic shape, and approximately 45 wt. % particles of aluminium hydroxide having a plate-like or plate-shaped basic shape. The matrix 2.1 consisting of SEBS therefore makes up approximately 25 wt. % of the injection moulding material 1. The aluminium particles can be obtained e.g. from the company Benda-Lutz GmbH. The aluminium hydroxide particles can be obtained e.g. from the company Nabaltec AG. This embodiment can also be implemented with particles of aluminium having a plate-like or plate-shaped basic shape and with particles of aluminium hydroxide having a round or rounded basic shape.

The composition of the injection moulding material 1 according to a second specific embodiment can be as follows: The matrix 2.1 consisting of SEBS contains approximately 30 wt. % particles of aluminium oxide having a plate-like or plate-shaped basic shape, and approximately 30 wt. % particles of boron nitride having a round or rounded basic shape. The matrix 2.1 consisting of SEBS therefore makes up approximately 25 wt. % of the injection moulding material 1. The aluminium oxide particles can be obtained e.g. from the companies Almatis GmbH, Bassermann, Huber Advanced Materials, Showa Denko or Silbelco. The boron nitride particles can be obtained e.g. from the companies 3M, Saint Gobain, Henze, Momentive or Kennametal. This embodiment can also be implemented with particles of aluminium oxide having a round or rounded basic shape and with particles of boron nitride having a plate-like or plate-shaped basic shape.

Alternative embodiments can alternatively or additionally comprise at least one of the following particle types as thermally conductive particles 2.2: thermal titanium particles, titanium oxide (TiO, TiO₂ or Ti₂O₃) particles, titanium hydroxide particles or mixtures of at least two of the above; zirconium particles, zirconium oxide (ZrO₂) particles, zirconium hydroxide (Zr(OH)₄) particles or mixtures of at least two of the above; magnesium particles, magnesium oxide (MgO) particles, magnesium hydroxide (Mg(OH)₂) particles or mixtures of at least two of the above; iron particles, iron oxide (Fe₂O₃ or Fe₃O₄) particles, iron hydroxide (Fe(OH)₃) particles or mixtures of at least two of the above; particles based on carbon, such as graphite and/or carbon black.

FIG. 2 is a flow diagram showing the steps of a method for processing an injection moulding material 1 according to an embodiment. The method in particular comprises the step S1: melting or plasticising the injection moulding material 1, and the step S2: injecting the melted or plasticised thermally conductive injection moulding material 1 into a shaping cavity of an injection mould. The method can in principle be carried out with any injection moulding machine, which typically comprises a plasticiser unit for plasticising the injection moulding material 1, and/or an injection unit, e.g. formed by or comprising a screw that is movably mounted within a corresponding cylinder, for injecting the plasticised injection moulding material 1 into a shaping cavity of an injection mould. The method can accordingly be implemented as an injection moulding process, in which the injection moulding material 1 is melted or plasticised and injected into a shaping cavity of an injection mould.

The method can be developed in that a component 3, to be overmoulded, at least in portions, with the injection moulding material 1, is arranged within the shaping cavity of the injection mould. In this respect, a method for producing a component arrangement that is provided at least in portions with a thermally conductive layer formed by a thermally conductive plastics body 5 can be implemented.

The method in particular comprises the following steps: Providing at least one component 3 that generates thermal energy (heat) in at least one operating state, in particular at least one electrical or electronic component that generates heat in at least one operating state, and overmoulding the at least one component 3, which generates heat in at least one operating state, at least in portions with a melted or plasticised injection moulding material 1, forming the component arrangement 4. The overmoulding of the at least one component 3 with the melted or plasticised injection moulding material 1 can take place in the context of a injection moulding process in which the injection moulding material 1 is melted or plasticised and injected into a shaping cavity of an injection mould, in which the at least one component 3 is arranged or held, in order to be overmoulded at least in portions with the melted or plasticised injection moulding material 1.

A component arrangement 4 produced in this way and shown schematically in FIG. 3 typically consists of the at least one component 3, i.e. e.g. an electrical and/or electronic component, and the thermally conductive plastics body 5 that covers said component at least in portions and is formed by cooling or hardening of the injection moulding material 1. In the embodiment, the component 3 comprises, by way of example, a printed circuit board 3.1 on which electrical or electronic structural elements 3.2 are arranged or formed.

It can be seen that the geometry of the plastics body 5 is based at least in portions on the geometry of the component 3, such that the plastics body 5 rests flat on the surface of the component 3, at least in portions, which leads to a good heat transfer from the component 3 to the plastics body 5. It can be seen that the thermally conductive plastics body 5 covers the component 3, i.e. the printed circuit board 3.1 and the structural elements 3.2, such that these are embedded in the injection moulding material 1 at least in portions, optionally completely.

Specifically, the component arrangement 4 can be an electrical or electronic control system, in particular an electrical or electronic accumulator or battery control system for an accumulator or a battery, of an accumulator or battery-operated tool, such as a screwdriving tool. In this case, the component 3 that is overmoulded at least in portions with the injection moulding material 1 can be a printed circuit board 3.1 or control board fitted with one or more electrical and/or electronic structural elements.

Even if this is not shown, the geometry of the thermally conductive plastics body 5 can comprise one or more cooling structures, e.g. cooling ribs, and/or one or more reinforcing structures, e.g. reinforcing ribs, which can be formed in one piece or integrally with the thermally conductive plastics body 5 in the context of the injection moulding process by corresponding shaping of the cavity of the respective injection mould.

The spraying—similar would in principle apply for other types of application or fastening—of a corresponding thermally conductive plastics body 5 from the injection moulding material 1 onto a corresponding component 3 makes it possible to reduce the operating temperature of the respective component 3 or the corresponding component arrangement 4, which can significantly lengthen the lifetime of the component 3 or the component arrangement 4.

1. A thermally conductive injection molding material that can be processed in an injection molding process, comprising a matrix which comprises at least one thermoplastic elastomer, wherein the matrix contains thermally conductive particles.

2. (canceled)

3. The thermally conductive injection molding material according to claim 1, wherein the matrix is formed by a thermoplastic elastomer based on a styrene-butadiene-styrene copolymer, SBS.

4. The thermally conductive injection molding material according to claim 1, wherein the matrix is formed by styrene-ethylene-butylene-styrene, SEBS.

5. The thermally conductive injection molding material according to claim 1, wherein the thermally conductive particles are or comprise metal particles and/or metal oxide particles.

6. The thermally conductive injection molding material according to claim 1, wherein the thermally conductive particles are or comprise aluminium particles aluminium oxide particles, aluminium hydroxide particles.

7. The thermally conductive injection molding material according to claim 1, wherein the fraction by weight of the thermally conductive particles in the matrix is in a range between 5 and 75 wt. %.

8. The thermally conductive injection molding material according to claim 1, wherein the matrix contains a first and at least one second type of thermally conductive particle which differ in their chemical composition.

9. The thermally conductive injection molding material according to claim 8, wherein the fraction by weight of the thermally conductive particles of the first type is in a range between 5 and 75 wt. % and the fraction by weight of the thermally conductive particles of the second type is in a range between 5 and 75 wt. %, wherein the sum of the fractions does not exceed 100 wt. %.

10. The thermally conductive injection molding material according to claim 8, wherein the thermally conductive particles of the first type are aluminium oxide particles, and the thermally conductive particles of the second type are nitride particles.

11. The thermally conductive injection molding material according to claim 1, wherein it has a thermal conductivity in a range between 0.5 and 2.5 W/mK.

12. The thermally conductive injection molding material according to claim 1, wherein it has a melt volume flow rate of 6 g/10 min in a molten state.

13. The thermally conductive injection molding material according to claim 1, wherein it has a combustion behaviour of the class v0 according to UL-94.

14. The thermally conductive injection molding material according to claim 1, wherein it has a hardness in a range between 10 and 80 Shore A.

15. The thermally conductive injection molding material according to claim 1, wherein it has a relative thermal index, RTI, of at least 80 °C.

16. The thermally conductive injection molding material according to claim 1, wherein it has electrically insulating properties.

17. A method for processing a thermally conductive injection molding material according to claim 1, comprising the steps of: melting the thermally conductive injection molding material and injecting the melted thermally conductive injection molding material into a shaping cavity of an injection mold.

18. A method for producing a component arrangement provided at least in portions with a thermally conductive layer, comprising the following steps:
providing at least one component that generates heat in at least one operating state,
overmolding the at least one component, which generates heat in at least one operating state, at least in portions with a melted thermally conductive injection molding material according to claim 1, forming the component arrangement.

19. A component arrangement produced according to a method according to claim 18, wherein the component arrangement comprises the at least one component, which is an electrical and/or electronic component, and a thermally conductive plastics body that covers it at least in portions and is formed by cooling or hardening of the injection molding material.

20. (canceled)

21. The component arrangement according to claim 19, wherein a geometry of the thermally conductive plastics body is based at least in portions on the geometry of the at least one component, such that the thermally conductive plastics body rests flat on a surface of the at least one component, at least in portions.

22. The component arrangement according to claim 19, wherein the component arrangement is an electrical or electronic control system.

23. (canceled)
